(19) United States
(12) Patent Application Publication
(10) Pub. No.: US 2023/0053559 A1
(43) Pub. Date: Feb. 23, 2023

(54) LEAD FRAME AND ELECTRONIC COMPONENT

(71) Applicant: TDK CORPORATION, Tokyo (JP)

(72) Inventors: Kazuma YAMAWAKI, Tokyo (JP); Shuhei MIYAZAKI, Tokyo (JP)

(73) Assignee: TDK CORPORATION, Tokyo (JP)

(21) Appl. No.: 17/857,872

(22) Filed: Jul. 5, 2022

(30) Foreign Application Priority Data
Aug. 20, 2021 (JP) 2021-134662

(51) Int. Cl. H01L 23/495; H01L 21/48

(52) U.S. Cl. CPC H01L 23/4952; H01L 23/49541; H01L 21/4825; H01L 21/4842; H01L 23/49582; H01L 21/56

(57) ABSTRACT

A lead frame includes a die pad, a plurality of leads, a frame member, and at least one wire. The frame member includes two first connection bars and two second connection bars. The plurality of leads include a plurality of specific leads. Each of the specific leads is connected to the first connection bar. At least one of the specific leads is connected to the second connection bar via the at least one wire.

### CROSS REFERENCE TO RELATED APPLICATIONS

This application claims the benefit of Japanese Priority Patent Application No. 2021-134662 filed on Aug. 20, 2021, the entire contents of which are incorporated herein by reference.

### BACKGROUND

The technology relates to a lead frame for an electronic component and an electronic component manufactured using the lead frame.

Packages such as Dual Flatpack No-leaded (DFN) packages that are provided with no lead terminals extending outward from a package body are known as packages for electronic components, such as semiconductor devices, suitable for miniaturization. In the DFN packages, a plurality of terminals are provided on a surface of a package body. The plurality of terminals are bonded to a conductive layer on a board by soldering, for example.

In general, a lead frame, which has a die pad on which a chip is mounted and a plurality of leads, is used to manufacture the DFN package. The plurality of terminals are formed by plating parts of surfaces of the plurality of leads. In order to form good fillets when mounting an electronic component on the board, it is desirable to plate the entire surfaces of the leads that are exposed from the surface of the package body.

US 2015/0255378 A1 and JP 2016-167532 A disclose a technology for plating entire surfaces of leads exposed from a surface of a package body. US 2015/0255378 A1 describes a lead frame in which inner leads are connected to outer leads connected to a lead frame rim. The inner leads are connected to the lead frame rim through inner lead suspension leads. The outer leads have a long shape in one direction. The inner leads and inner lead suspension leads extend in a direction orthogonal to a longitudinal direction of the outer leads.

In US 2015/0255378 A1, the outer leads are cut from the lead frame rim after a semiconductor chip is encapsulated by an encapsulating resin. After the outer leads are cut, the lead frame rim and the outer leads still maintain an electrical connection relationship. In US 2015/0255378 A1, plating is applied in this state to form a plated film on entire surfaces of the outer leads exposed from the encapsulating resin.

JP 2016-167532 A describes a lead frame similar to the lead frame described in US 2015/0255378 A1. A first connection bar and a second connection bar of JP 2016-167532 A correspond to the lead frame rim of US 2015/0255378 A1. In JP 2016-167532 A, extensions are connected to leads connected to the first connection bar. The extensions are connected to the second connection bar. The leads have a long shape in one direction. The extensions extend in a direction orthogonal to a longitudinal direction of the leads.

In the lead frames described in US 2015/0255378 A1 and JP 2016-167532 A, leads to be used as terminals and ones not to be used as terminals are coupled to each other. If an electronic component is manufactured using such a lead frame, the leads not to be used as terminals are also exposed from the package body. This increases the number of leads exposed from the package body and increases the risk of moisture intrusion into the package body through the interfaces between the leads and the encapsulating resin. The risk increases with an increase in the exposed area of the leads not to be used as terminals.

### SUMMARY

A lead frame according to an embodiment of the technology is a lead frame for an electronic component. The lead frame includes a die pad, a plurality of leads, a frame member configured to surround the die pad and the plurality of leads, and at least one wire. The frame member includes a first connection bar extending in a first direction and a second connection bar extending in a second direction. The plurality of leads include a plurality of specific leads arranged along the first connection bar. The plurality of specific leads are each connected to the first connection bar. At least one of the specific leads is connected to the second connection bar via the at least one wire.

In the lead frame according to the embodiment of the technology, a part of the at least one wire may be disposed in an area to be removed in a manufacturing process of the electronic component.

In the lead frame according to the embodiment of the technology, the at least one wire may be directly connected to at least one of the specific leads.

In the lead frame according to the embodiment of the technology, the at least one wire may be directly connected to the second connection bar. In such a case, the second connection bar may be plated with Au, Ag, Cu, Ni, or Pd-PPF. PPF is an abbreviation of Pre Plated Leadframe. Pd-PPF refers to a plurality of plating layers of Ni, Pd, and Au.

The lead frame according to the embodiment of the technology may further include at least one connecting lead connected to the second connection bar. At least one of the specific leads may be connected to the at least one connecting lead via the at least one wire. The at least one connecting lead may be plated with Au, Ag, Cu, Ni, or Pd-PPF.

If the lead frame according to the embodiment of the technology includes the at least one connecting lead, the at least one wire may include a plurality of wires. The at least one connecting lead may include one connecting lead. The plurality of specific leads may be connected to the one connecting lead via the plurality of wires. In such a case, the at least one connecting lead may include a wide portion. The wide portion may have a first dimension in the first direction and a second dimension in the second direction. The second dimension may be greater than or equal to the first dimension. When seen in a third direction orthogonal to the first and second directions, the wide portion may have an n-gon shape where n is 4 or more, a circular shape, or an elliptical shape.

If the at least one connecting lead includes the wide portion, the at least one connecting lead may further include a connection portion that connects the wide portion and the second connection bar. The wide portion may be disposed in an area to be removed in a manufacturing process of the electronic component.

An electronic component according to an embodiment of the technology is an electronic component manufactured using the lead frame according to the embodiment of the technology. The electronic component includes a chip mounted on the die pad, and an encapsulating resin that encapsulates the die pad, the plurality of leads, and the chip. Each of the leads has an exposed surface that is not covered with the encapsulating resin.

The electronic component according to the embodiment of the technology may further include a plating layer configured to cover the exposed surface.

In the lead frame and the electronic component according to the embodiment of the technology, at least one of the specific leads is connected to the second connection bar via the at least one wire. According to the embodiment of the technology, the risk of moisture intrusion into the package body can thereby be reduced.

Other and further objects, features and advantages of the technology will appear more fully from the following description.

### BRIEF DESCRIPTION OF THE DRAWINGS

The accompanying drawings are included to provide a further understanding of the disclosure and are incorporated in and constitute a part of this specification. The drawings show example embodiments and, together with the specification, serve to explain the principles of the technology.

FIG. 1 is a perspective view of an electronic component according to a first example embodiment of the technology.

FIG. 2 is a perspective view of the electronic component according to the first example embodiment of the technology.

FIG. 3 is an enlarged perspective view of a part of the electronic component illustrated in FIG. 2.

FIG. 4 is a plan view of a lead frame structure in the first example embodiment of the technology.

FIG. 5 is a plan view of a lead frame according to the first example embodiment of the technology.

FIG. 6 is an enlarged plan view of a part of the lead frame illustrated in FIG. 5.

FIG. 7 is a plan view of a lead frame according to a second example embodiment of the technology.

FIG. 8 is an enlarged plan view of a part of the lead frame illustrated in FIG. 7.

FIG. 9 is a plan view of a first modification example of the lead frame according to the second example embodiment of the technology.

FIG. 10 is a plan view of a second modification example of the lead frame according to the second example embodiment of the technology.

FIG. 11 is a plan view of a third modification example of the lead frame according to the second example embodiment of the technology.

FIG. 12 is a plan view of a fourth modification example of the lead frame according to the second example embodiment of the technology.

### DETAILED DESCRIPTION

An object of the technology is to provide a lead frame that can reduce the risk of moisture intrusion into a package body, and an electronic component using the lead frame.

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions. Note that the description is given in the following order.

### First Example Embodiment

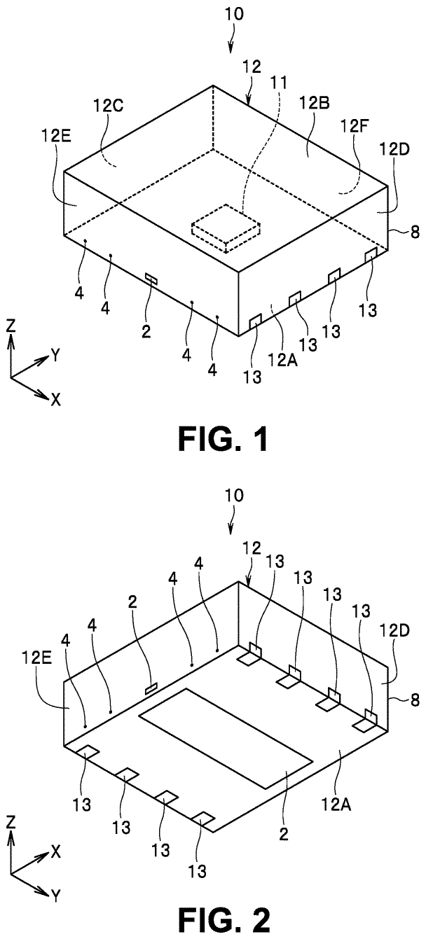

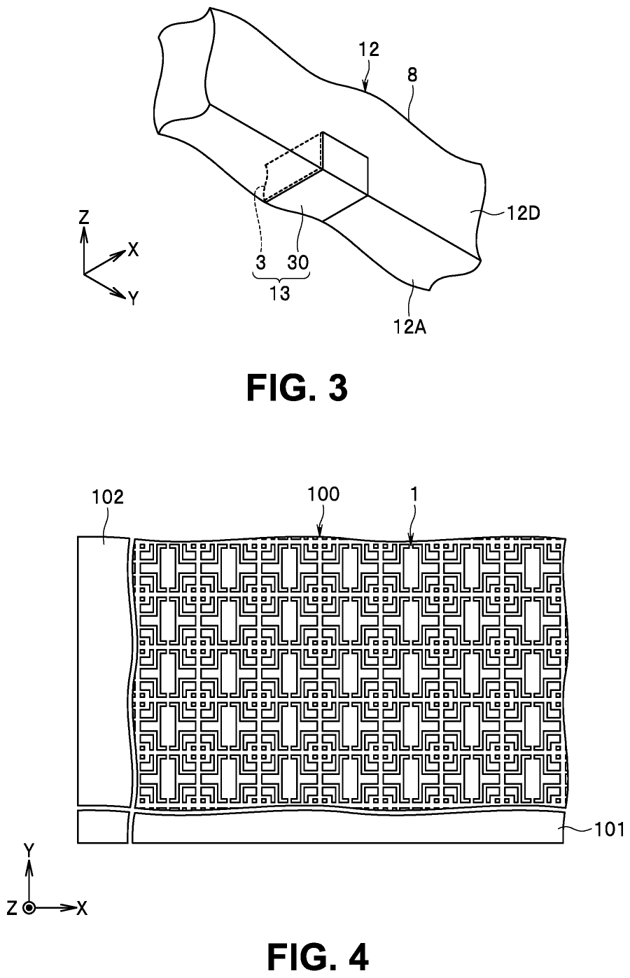

Example embodiments of the technology will now be described in detail with reference to the drawings. First, with reference to FIGS. 1 to 3, an electronic component according to a first example embodiment of the technology will be described. FIGS. 1 and 2 are perspective views of the electronic component. FIG. 3 is an enlarged perspective view of a part of the electronic component illustrated in FIG. 2.

An electronic component 10 according to the example embodiment is an electronic component manufactured using a lead frame according to the example embodiment. The electronic component 10 includes a chip 11, an encapsulating resin 8, and a plurality of terminals 13. The chip 11 is mounted on a die pad 2 of the lead frame. The chip 11 has a plurality of electrode pads. The plurality of electrode pads are connected to a plurality of leads 3 of the lead frame by a plurality of bonding wires not-shown. The encapsulating resin 8 encapsulates the die pad 2, the plurality of leads 3, and the chip 11. The encapsulating resin 8 constitutes a large portion of a package body (hereinafter simply referred to as a body) 12 of the electronic component 10.

In particular, in the example embodiment, the body 12 is approximately in the shape of a rectangular parallelepiped. The body 12 has a bottom surface 12A, a top surface 12B, and four side surfaces 12C to 12F, which constitute an outer periphery of the body 12. The bottom surface 12A and the top surface 12B are opposite to each other. The side surfaces 12C and 12D are opposite to each other. The side surfaces 12E and 12F are opposite to each other. The side surfaces 12C to 12F are perpendicular to the bottom surface 12A and the top surface 12B. FIG. 1 illustrates the electronic component 10 viewed from the side of the top surface 12B. FIG. 2 illustrates the electronic component 10 viewed from the side of the bottom surface 12A.

Here, X, Y, and Z directions are defined as shown in FIGS. 1 to 3. The X, Y, and Z directions are orthogonal to one another. In the example embodiment, the Z direction refers to a direction that is perpendicular to the bottom surface 12A and that is pointing to the top surface 12B from the bottom surface 12A. The opposite directions to the X, Y, and Z directions are defined as −X, −Y, and −Z directions, respectively.

In the example embodiment, the Y direction corresponds to a “first direction” in the technology. The X direction corresponds to a “second direction” in the technology. The Z direction corresponds to a “third direction” in the technology. The first direction, the second direction, and the third direction may be orthogonal to each other.

As illustrated in FIGS. 1 and 2, the bottom surface 12A is located at an end of the body 12 in the −Z direction. The top surface 12B is located at an end of the body 12 in the Z direction. The side surface 12C is located at an end of the body 12 in the −X direction. The side surface 12D is located at an end of the body 12 in the X direction. The side surface 12E is located at an end of the body 12 in the −Y direction. The side surface 12F is located at an end of the body 12 in the Y direction.

Some of the terminals 13 are arranged on and near a ridge line between the bottom surface 12A and the side surface 12C. In the example illustrated in FIGS. 1 and 2, four terminals 13 aligned in the Y direction are arranged on and near the ridge line between the bottom surface 12A and the side surface 12C. Similarly, some of the other terminals of the plurality of terminals 13 are arranged on and near a ridge line between the bottom surface 12A and the side surface 12D. In the example illustrated in FIGS. 1 and 2, four terminals 13 aligned in the Y direction are arranged on and near the ridge line between the bottom surface 12A and the side surface 12D.

As illustrated in FIG. 3, each of the leads 3 has an exposed surface that is not covered with the encapsulating resin 8. The electronic component 10 further includes a plurality of plating layers 30 that cover the exposed surfaces of the plurality of leads 3, respectively. Each of the terminals 13 is constituted of the lead 3 and the plating layer 30.

The die pad 2 has an exposed surface that is not covered with the encapsulating resin 8. Most of the exposed surface of the die pad 2 is located on the bottom surface 12A. The electronic component 10 further has a not-shown plating layer, which covers a portion of the exposed surface of the die pad 2 that is located on the bottom surface 12A.

The portions of the exposed surface of the die pad 2, which are not disposed on the bottom surface 12A, are arranged on the side surfaces 12E and 12F. The portions of the exposed surface of the die pad 2 that are arranged on the side surfaces 12E and 12F may not be covered with the plating layer.

The electronic component 10 is mounted on a mounting board with the bottom surface 12A of the body 12 facing the mounting board. The electronic component 10 illustrated in FIGS. 1 to 3 is a Dual Flatpack No-leaded (DFN) package having no lead terminals extending outward from the body 12.

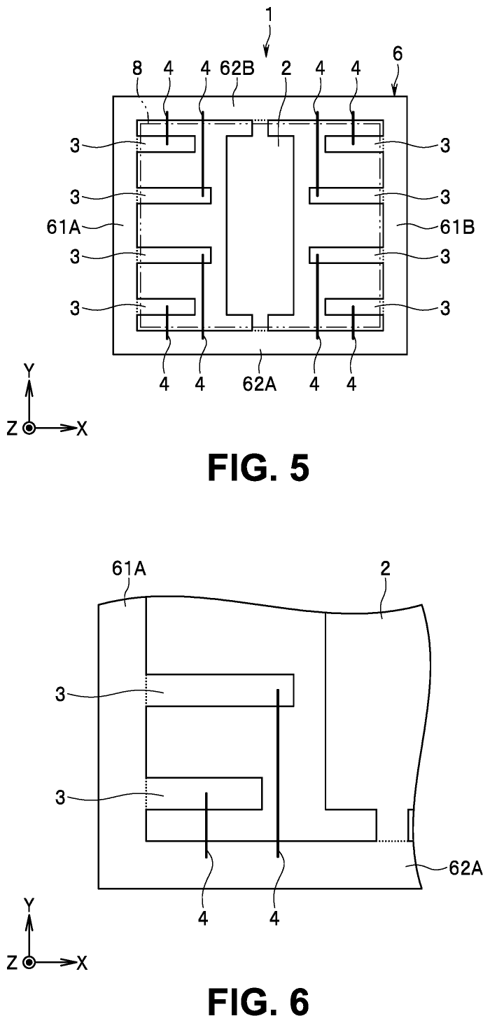

Next, the lead frame according to the example embodiment will be described with reference to FIGS. 4 to 6. FIG. 4 is a plan view of a lead frame structure in the example embodiment. FIG. 5 is a plan view of a lead frame according to the example embodiment. FIG. 6 is an enlarged plan view of a part of the lead frame illustrated in FIG. 5. In FIGS. 4 to 6, the X, Y, and Z directions are illustrated as in FIGS. 1 to 3. In FIGS. 4 to 6, the X, Y and Z directions are defined such that the relationship between the orientation of die pad 2 and the X, Y, and Z directions is the same as in FIGS. 1 to 3.

A lead frame structure 100 illustrated in FIG. 4 includes a plurality of lead frames 1 for the electronic components 10. In the example illustrated in FIG. 4, the plurality of lead frames 1 are arranged such that multiple lead frames 1 align with one another in the X and Y directions, respectively. The lead frame structure 100 is made by processing a metal plate made of an alloy containing Cu or Fe, for example.

The structure of the lead frames 1 will be described below, focusing on one lead frame 1. The lead frame 1 includes the die pad 2, the plurality of leads 3, and a frame member 6 surrounding the die pad 2 and the plurality of leads 3.

The frame member 6 includes two first connection bars 61A and 61B each extending in the Y direction, and two second connection bars 62A and 62B each extending in the X direction. One end of the first connection bar 61A is connected to one end of the second connection bar 62A. The other end of the second connection bar 62A is connected to one end of the first connection bar 61B. The other end of the first connection bar 61B is connected to one end of the second connection bar 62B. The other end of the second connection bar 62B is connected to the other end of the first connection bar 61A.

One end of the die pad 2 is connected to the second connection bar 62A. The other end of the die pad 2 is connected to the second connection bar 62B. In FIG. 5, a boundary between the die pad 2 and the second connection bar 62A, and a boundary between the die pad 2 and the second connection bar 62B are indicated by dotted lines.

The lead frame 1 has eight leads 3 serving as the plurality of leads 3. Each of the eight leads 3 extends in the X direction. Four of the leads 3 are arranged between the die pad 2 and the first connection bar 61A so as to be aligned along the first connection bar 61A. The four leads 3 are each connected to the first connection bar 61A. In FIG. 5, boundaries between each of the four leads 3 and the first connection bar 61A are indicated by dotted lines.

The other four leads 3 are arranged between the die pad 2 and the first connection bar 61B so as to be aligned along the first connection bar 61B. The other four leads 3 are each connected to the first connection bar 61B. In FIG. 5, boundaries between each of the other four leads 3 and the first connection bar 61B are indicated by dotted lines.

The lead frame 1 further includes at least one wire 4. In particular, in the example embodiment, the lead frame 1 includes eight wires 4 as the at least one wire 4.

Of the four leads 3 arranged along the first connection bar 61A, the lead 3 located at the end in the −Y direction and the lead 3 adjacent to this lead 3 at the end will be referred to as specific leads. FIG. 6 shows the two specific leads 3.

At least one of the two specific leads 3 is connected to the second connection bar 62A via at least one wire 4. In the example embodiment, the two specific leads 3 are connected to the second connection bar 62A via two wires 4 each.

In the example embodiment, the wires 4 are directly connected to the specific leads 3 and directly connected to the second connection bar 62A. The second connection bar 62A may be plated with Au, Ag, Cu, Ni, or Pd-PPF. PPF is an abbreviation of Pre Plated Leadframe. Pd-PPF refers to a plurality of plating layers of Ni, Pd, and Au.

With replacement of the second connection bar 62A with the second connection bar 62B, the foregoing description of the two specific leads 3 also applies to, of the four leads 3 arranged along the first connection bar 61A, the lead 3 located at an end in the Y direction and the lead 3 adjacent to this lead 3 at the end. Similarly, with replacement of the first connection bar 61A with the first connection bar 61B, the foregoing description of the four leads 3 arranged along the first connection bar 61A also applies to the four leads 3 arranged along the first connection bar 61B.

In FIG. 5, the area enclosed by the dashed double-dotted rectangle with the reference numeral 8 indicates an area encapsulated by the encapsulating resin 8 in the electronic component 10 manufactured using the lead frame 1. The area outside the dashed double-dotted rectangle with the reference numeral 8 is an area that is to be removed in a manufacturing process of the electronic component 10. The first connection bars 61A and 61B and the second connection bars 62A and 62B are located in the area to be removed in the manufacturing process of electronic component 10. In the manufacturing process of the electronic component 10, the leads 3 are also removed at a portion in the vicinity of the boundary between the lead 3 and the first connection bar 61A or 61B.

In the manufacturing process of the electronic component 10, the portion of the die pad 2 near the boundary with the second connection bar 62A and the portion near the boundary with the second connection bar 62B are also removed. Consequently, as shown in FIGS. 1 and 2, the end faces of the die pad 2 are exposed at the side surfaces 12E and 12F of the body 12 of the electronic component 10.

A part of each of the eight wires 4 is also disposed in an area to be removed in the manufacturing process of the electronic component 10. In the manufacturing process of the electronic component 10, the wires 4 are cut off in removing the second connection bars 62A and 62B. Consequently, as shown in FIGS. 1 and 2, the cut surfaces of the wires 4 are exposed at the side surfaces 12E and 12F of the body 12 of the electronic component 10.

So far, focus has been placed on the describing of the single lead frame 1. As described above, the lead frame structure 100 in the example embodiment includes the plurality of lead frames 1. The lead frame structure 100 also includes a plurality of first connection bars 61A, a plurality of first connection bars 61B, a plurality of second connection bars 62A, and a plurality of second connection bars 62B.

The plurality of first connection bars 61A and the plurality of first connection bars 61B are arranged in the X direction such that the first connection bars 61A and the first connection bars 61B are alternately disposed. Each of the first connection bars 61A and 61B has, in a direction parallel to the Y direction, a dimension corresponding to the plurality of lead frames 1 aligned in the Y direction.

The plurality of second connection bars 62A and the plurality of second connection bars 62B are arranged in the Y direction, such that the second connection bars 62A and the second connection bars 62B are alternately disposed and cross the plurality of first connection bars 61A and 61B. Each of the second connection bars 62A and 62B has, in a direction parallel to the X direction, a dimension corresponding to the plurality of lead frames 1 aligned in the X direction.

The lead frame structure 100 includes a third connection bar 101 located at an end of the lead frame structure 100 in the −Y direction, a not-shown fourth connection bar located at an end of the lead frame structure 100 in the Y direction, a fifth connection bar 102 located at an end of the lead frame structure 100 in the −X direction, and a not-shown sixth connection bar located at an end of the lead frame structure 100 in the X direction. The plurality of first connection bars 61A and the plurality of first connection bars 61B are each connected to the third connection bar 101 and the fourth connection bar. The plurality of second connection bars 62A and the plurality of second connection bars 62B are each connected to the fifth connection bar 102 and the sixth connection bar.

Next, a manufacturing method of the electronic component 10 will be described with reference to FIGS. 4 to 6. In the manufacturing method of the electronic component 10, first, the chips 11 are mounted on the die pads 2 of the lead frames 1. Next, the plurality of electrode pads of each chip 11 are connected to the plurality of leads 3 of each lead frame 1 by bonding wires. Next, an encapsulating process is performed in which the die pads 2, the plurality of leads 3, and the chips 11 are encapsulated with the encapsulating resin 8. In the encapsulating process, the first connection bars 61A and 61B and the second connection bars 62A and 62B of the frame members 6 of the lead frames 1 are also encapsulated. Hereafter, a structure produced in the encapsulating process, which includes the lead frames 1 and the encapsulating resin 8, is referred to as a basic structure.

In the basic structure, a part of each of the leads 3 near the first connection bar 61A or 61B may be exposed from the portion of the encapsulating resin 8 to be the bottom surface 12A of the body 12. In the basic structure, a part of the die pad 2 may be exposed from the portion of the encapsulating resin 8 to be the bottom surface 12A of the body 12. The lead frame 1 may have a structure such that a part of each of the leads 3 and a part of the die pad 2 are exposed, as described above. Alternatively, prior to the encapsulating process, the lead frame 1 may be processed such that a part of each of the leads 3 and a part of the die pad 2 are exposed, as described above.

In the manufacturing method of the electronic component 10, the basic structure is then secured to a not-shown dicing tape. Next, a cutting process is performed in which the basic structure is cut by a dicing saw such that the first connection bars 61A and 61B are removed. By the cutting process, cut surfaces of the plurality of leads 3 are exposed from the encapsulating resin 8. In the cutting process, the basic structure may be cut such that the basic structure is not divided, in other words, such that the third connection bar 101 and the fourth connection bar are not completely cut off. The plurality of leads 3 are connected to the second connection bars 62A and 62B via the plurality of wires 4, respectively. The second connection bars 62A and 62B are connected to the fifth connection bar 102 and the sixth connection bar.

In the manufacturing method of the electronic component 10, the plating layer 30 is then formed on surfaces of the plurality of leads 3 exposed from the encapsulating resin 8, as well as on a surface of the die pad 2 exposed from the encapsulating resin 8 by electroplating, for example. When using the electroplating, the plating layer can be formed by connecting an electrode of an electroplating device to at least one of the third connection bar 101, the not-shown fourth connection bar, the fifth connection bar 102, and the not-shown sixth connection bar.

In the manufacturing method of the electronic component 10, next, the plurality of electronic components 10 are divided from one another by cutting the basic structure such that the second connection bars 62A and 62B are removed. Thereby, the electronic component 10 is completed.

Next, the operation and effects of the lead frame 1 and the electronic component 10 according to the example embodiment will be described. The plurality of leads 3 are each connected to the first connection bar 61A or 61B. Now, take a lead frame of a comparative example where each of the leads 3 is connected to the second connection bar 62A or 62B by a connecting lead having a constant width instead of a wire 4. If the electronic component 10 is manufactured using the lead frame of the comparative example, the cut surfaces of the connecting leads are exposed at the side surfaces 12E and 12F of the body 12 of the electrode component 10.

In the electronic component 10 manufactured using the lead frame of the comparative example, the number of leads exposed from the body 12 increases by the number of connecting leads. As a result, the electronic component 10 manufactured using the lead frame of the comparative example has a higher risk of moisture intrusion into the body 12 through the interfaces between the leads and the encapsulating resin 8. The risk increases as the cut surfaces of the connecting leads increase in area.

By contrast, in the example embodiment, each of the leads 3 is connected to the second connection bar 62A or 62B via the wire 4. As described above, the cut surfaces of the wires 4 are exposed at the side surfaces 12E and 12F of the body 12 of the electronic component 10. The cut surfaces of the wires 4 are smaller than those of the connecting leads. In the example embodiment, the risk of moisture intrusion into the body 12 is low as compared to the case where the connecting leads are used. According to the example embodiment, the risk of moisture intrusion into the body 12 can thus be reduced by the use of the wires 4.

Moreover, according to the example embodiment, the wear of the dicing saw can be reduced since the cut surfaces of the wires 4 are smaller than those of the connecting leads.

### Second Example Embodiment

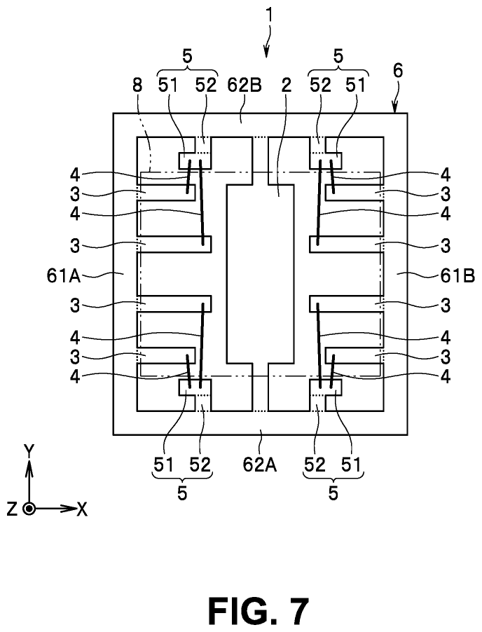

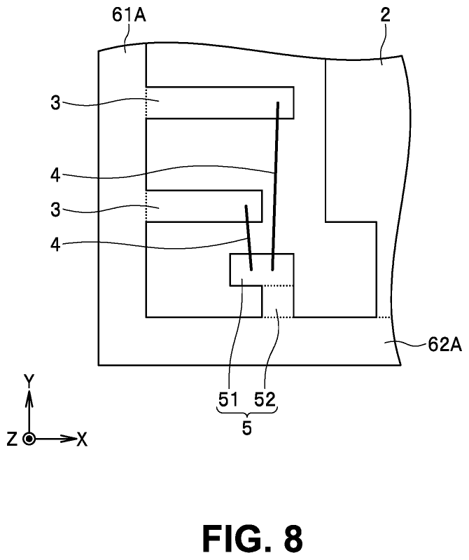

A second example embodiment of the technology will now be described with reference to FIGS. 7 and 8. FIG. 7 is a plan view of a lead frame according to the example embodiment. FIG. 8 is an enlarged plan view of a part of the lead frame illustrated in FIG. 7.

A lead frame 1 according to the example embodiment includes at least one connecting lead. At least one of leads 3 is connected to the at least one connecting lead via at least one wire 4. In particular, in the example embodiment, the lead frame 1 includes four connecting leads 5 as the at least one connecting lead. Each of the four connecting leads 5 may be plated with Au, Ag, Cu, Ni, or Pd-PPF.

The four connecting leads 5 each include a wide portion 51 and a connection portion 52. The wires 4 connect the leads 3 and the wide portions 51. The connection portions 52 connect the wide portions 51 and the second connection bars 62A or 62B. In FIGS. 7 and 8, the boundaries between the wide portions 51 and the connection portions 52 and the boundaries between the connection portions 52 and the second connection bars 62A or 62B are shown by respective dotted lines.

FIG. 8 shows the two specific leads 3 described in the first example embodiment. The two specific leads 3 are connected to a wide portion 51. With replacement of the second connection bar 62A with the second connection bar 62B, the foregoing description of the two specific leads 3 also applies to, of the four leads 3 arranged along the first connection bar 61A, the lead 3 located at an end in the Y direction and the lead 3 adjacent to this lead 3 at the end. Similarly, with replacement of the first connection bar 61A with the first connection bar 61B, the foregoing description of the four leads 3 arranged along the first connection bar 61A also applies to the four leads 3 arranged along the first connection bar 61B.

In FIG. 7, the area enclosed by the dashed double-dotted rectangle with the reference numeral 8 indicates an area encapsulated by the encapsulating resin 8 in the electronic component 10 manufactured using the lead frame 1 according to the example embodiment. The area outside the dashed double-dotted rectangle with the reference numeral 8 is an area that is to be removed in the manufacturing process of the electronic component 10. The first connection bars 61A and 61B, the second connection bars 62A and 62B, and the connecting leads 5 (wide portions 51 and connection portions 52) are disposed in areas to be removed in the manufacturing process of the electronic component 10.

Next, the shape (planar shape) of the wide portion 51 seen in the Z direction will be described with reference to FIG. 8. In the example embodiment, the wide portion 51 has a quadrangular planar shape. Two sides of this quadrangle are parallel to the X direction, and the other two sides of this quadrangle are parallel to the Y direction.

The wide portion 51 has a first dimension in the Y direction and a second dimension in the X direction. The second dimension may be equal to or more than the first dimension. When the second dimension is equal to the first dimension, the planar shape of the wide portion 51 is square. When the second dimension is more than the first dimension, the planar shape of the wide portion 51 is rectangular.

Next, the manufacturing method of the electronic component 10 according to the example embodiment will be described. The manufacturing method of the electronic component 10 according to the example embodiment is the same as that according to the first example embodiment, up to the process of forming the plating layer 30 on the surfaces of the plurality of leads 3 exposed from the encapsulating resin 8, as well as on the surface of the die pad 2 exposed from the encapsulating resin 8. In the example embodiment, the plurality of electronic components 10 are divided from one another by cutting the basic structure such that the second connection bars 62A and 62B, and the connecting leads 5 are removed. Thereby, the electronic component 10 is completed.

### Modification Examples

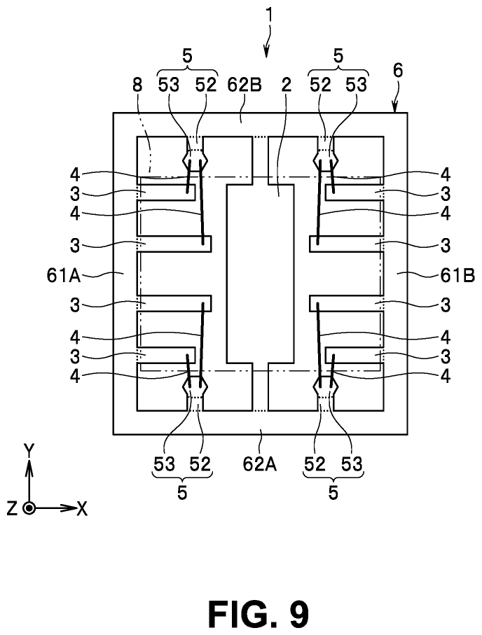

Next, first to fourth modification examples of the lead frame 1 according to the example embodiment will be described. First, the first modification example of the lead frame 1 will be described with reference to FIG. 9. In the first modification example, each of the four connecting leads 5 includes a wide portion 53 instead of the wide portion 51 shown in FIGS. 7 and 8. In FIG. 9, the boundaries between the wide portions 53 and the connection portions 52 are shown by dotted lines. The wide portions 53 have a polygonal planar shape. In particular, in the example shown in FIG. 9, the wide portions 53 have a hexagonal planar shape. If the wide portions 53 have a polygonal planar shape, the polygonal shape is not limited to a rectangular or hexagonal shape and may be an n-gon shape where n is 4 or more.

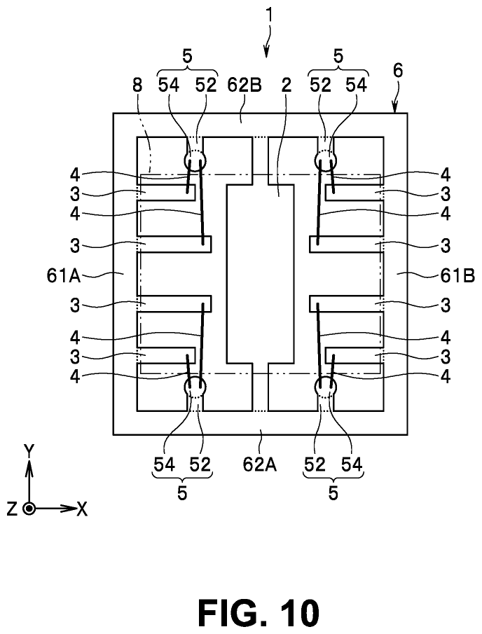

Next, the second modification example of the lead frame 1 will be described with reference to FIG. 10. In the second modification example, each of the four connecting leads 5 includes a wide portion 54 instead of the wide portion 51 shown in FIGS. 7 and 8. In FIG. 10, the boundaries between the wide portions 54 and the connection portions 52 are shown by dotted lines. The planar shape of the wide portions 54 is a circle.

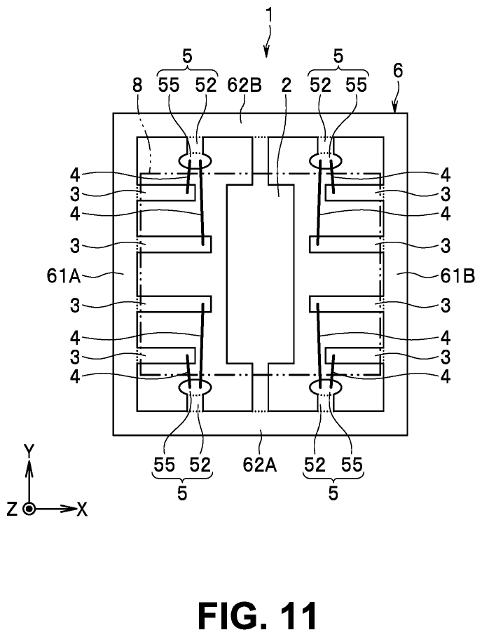

Next, the third modification example of the lead frame 1 will be described with reference to FIG. 11. In the third modification example, each of the four connecting leads 5 includes a wide portion 55 instead of the wide portion 51 shown in FIGS. 7 and 8. In FIG. 11, the boundaries between the wide portions 55 and the connection portions 52 are shown by dotted lines. The planar shape of the wide portions 55 is an ellipse.

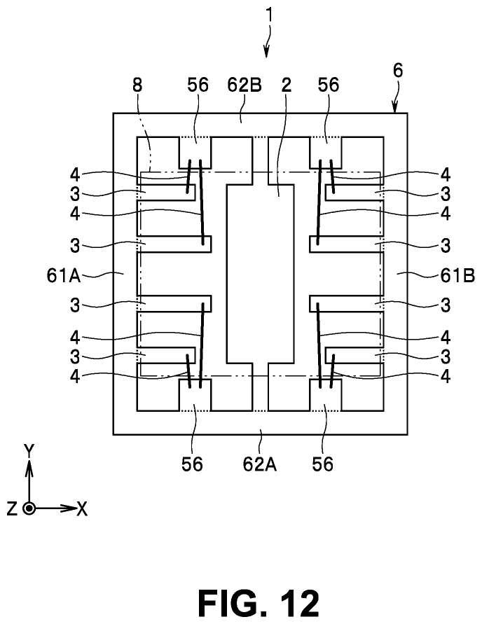

Next, the fourth modification example of the lead frame 1 will be described with reference to FIG. 12. In the fourth modification example, the lead frame 1 includes four connecting leads 56, instead of the four connecting leads 5. The planar shape of each of the four connecting leads 56 is rectangular. Each of the four connecting leads 56 may be plated with Au, Ag, Cu, Ni, or Pd-PPF.

The wires 4 connect the leads 3 and the connecting leads 56. The connecting leads 56 are directly connected to the second connection bar 62A or 62B. In FIG. 12, the boundaries between the connecting leads 56 and the second connection bars 62A or 62B are shown by dotted lines.

The configuration, operation and effects of the present example embodiment are otherwise the same as those of the first example embodiment.

The technology is not limited to the foregoing example embodiments, and various modifications may be made thereto. For example, the shapes, numbers, and layout of the leads and the connecting leads are not limited to the examples described in the example embodiments and may be optional as long as the requirements set forth in the claims are satisfied. The connecting leads and the wide portions may have other planar shapes such as a rounded-cornered polygonal shape and a partially circular or elliptical shape.

Some of the leads 3 may be connected to the second connection bar 62A or 62B by connecting leads instead of the wires 4.

Obviously, many modifications and variations of the technology are possible in the light of the above teachings. Thus, it is to be understood that, within the scope of the appended claims and equivalents thereof, the technology may be practiced in other embodiments than the foregoing example embodiments.

What is claimed is:

1. A lead frame for an electronic component, comprising
a die pad;
a plurality of leads;
a frame member configured to surround the die pad and the plurality of leads; and
at least one wire, wherein
the frame member includes a first connection bar extending in a first direction and a second connection bar extending in a second direction,
the plurality of leads include a plurality of specific leads arranged along the first connection bar,
the plurality of specific leads are each connected to the first connection bar, and
at least one of the specific leads is connected to the second connection bar via the at least one wire.

2. The lead frame according to claim 1, wherein a part of the at least one wire is disposed in an area to be removed in a manufacturing process of the electronic component.

3. The lead frame according to claim 1, wherein the at least one wire is directly connected to at least one of the specific leads.

4. The lead frame according to claim 1, wherein the at least one wire is directly connected to the second connection bar.

5. The lead frame according to claim 4, wherein the second connection bar is plated with Au, Ag, Cu, Ni, or Pd-PPF.

6. The lead frame according to claim 1, further comprising at least one connecting lead connected to the second connection bar, wherein
at least one of the specific leads is connected to the at least one connecting lead via the at least one wire.

7. The lead frame according to claim 6, wherein the at least one connecting lead is plated with Au, Ag, Cu, Ni, or Pd-PPF.

8. The lead frame according to claim 6, wherein
the at least one wire includes a plurality of wires,
the at least one connecting lead includes one connecting lead, and
the plurality of specific leads are connected to the one connecting lead via the plurality of wires.

9. The lead frame according to claim 8, wherein
the at least one connecting lead includes a wide portion,
the wide portion has a first dimension in the first direction and a second dimension in the second direction, and
the second dimension is greater than or equal to the first dimension.

10. The lead frame according to claim 8, wherein
the at least one connecting lead includes a wide portion, and
when seen in a third direction orthogonal to the first and second directions, the wide portion has an n-gon shape where n is 4 or more, a circular shape, or an elliptical shape.

11. The lead frame according to claim 9, wherein the at least one connecting lead further includes a connection portion that connects the wide portion and the second connection bar.

12. The lead frame according to claim 9, wherein the wide portion is disposed in an area to be removed in a manufacturing process of the electronic component.

13. An electronic component manufactured using the lead frame according to claim 1, the electronic component comprising:
a chip mounted on the die pad; and
an encapsulating resin that encapsulates the die pad, and the chip, wherein
each of the leads has an exposed surface that is not covered with the encapsulating resin.

14. The electronic component according to claim 13, further comprising a plating layer configured to cover the exposed surface.
